(19) United States
(12) Patent Application Publication
(10) Pub. No.: US 2026/0150192 A1
(43) Pub. Date: May 28, 2026

(54) PRINTED CIRCUIT BOARD

(71) Applicant: SAMSUNG ELECTRO-MECHANICS CO., LTD., Suwon-si (KR)

(72) Inventors: Chan Hoon KO, Suwon-si (KR); Sang Hoon KIM, Suwon-si (KR); Ki Eun CHO, Suwon-si (KR); Ji Ho YOON, Suwon-si (KR); Min Jae SEONG, Suwon-si (KR)

(73) Assignee: SAMSUNG ELECTRO-MECHANICS CO., LTD., Suwon-si (KR)

(21) Appl. No.: 19/246,011

(22) Filed: Jun. 23, 2025

(30) Foreign Application Priority Data
Nov. 26, 2024 (KR) 10-2024-0170432

(51) Int. Cl. H05K 1/11; H05K 3/28

(52) U.S. Cl. CPC H05K 1/111; H05K 3/28

(57) ABSTRACT

A printed circuit board includes an insulating layer, a first pad disposed on the insulating layer, and a protective layer disposed on the insulating layer. The protective layer includes a base portion having an opening exposing a portion of the first pad, a dam portion disposed on the base portion, the dam portion having a width less than that of the base portion, and a connection portion between the base portion and the dam portion. The connection portion has a width greater than that of the dam portion and less than that of the base portion. The base portion, the dam portion, and the connection portion are integrally formed.

### CROSS-REFERENCE TO RELATED APPLICATION(S)

This application claims benefit of priority to Korean Patent Application No. 10-2024-0170432 filed on Nov. 26, 2024 in the Korean Intellectual Property Office, the disclosure of which is incorporated herein by reference in its entirety.

### TECHNICAL FIELD

The present disclosure relates to a printed circuit board.

In response to the recent trend for miniaturization and weight reductions in mobile devices, there is an increasing need to achieve miniaturization and weight reduction in printed circuit boards (PCBs) mounted in such devices. As mobile devices have reduced weights and sizes, an undercut phenomenon may occur during the fabrication of microcircuits, which may lead to defects in the microcircuits. To meet such technical demands, research has been continuously conducted to improve the reliability of microcircuits while implementing microcircuits with reduced linewidths and distances therebetween.

### SUMMARY

An aspect of the present disclosure is to provide a printed circuit board including a protective layer protecting a pad, the protective layer having improved structural stability.

According to an aspect of the present disclosure, there is provided a printed circuit board including an insulating layer, a first pad disposed on the insulating layer, and a protective layer disposed on the insulating layer. The protective layer may include a base portion having an opening exposing a portion of the first pad, a dam portion disposed on the base portion, the dam portion having a width less than that of the base portion, and a connection portion between the base portion and the dam portion. The connection portion may have a width greater than that of the dam portion and less than that of the base portion. The base portion, the dam portion, and the connection portion may be integrally formed.

The connection portion may include a curved surface.

A side surface of the dam portion, spaced apart from the base portion, may have a planar surface.

The planar surface may be vertically disposed with respect to an upper surface of the insulating layer.

A lower surface of the base portion may be in contact with a region of the first pad, not exposed by the opening.

The printed circuit board may further include a conductor layer disposed on the insulating layer, the conductor layer having an upper surface covered by the base portion.

The connection portion may have a width gradually increasing from an upper portion to a lower portion of the dam portion.

The connection portion may include a plurality of side surfaces, discontinuously connected to each other.

The connection portion may include a first side surface and a second side surface disposed in sequence from a position closer to the base portion. Each of the first and second side surfaces may have a width gradually increasing from an upper portion to a lower portion of the dam portion.

Each of the plurality of side surfaces may include a curved surface.

The printed circuit board may further include a second pad disposed on the outside of the dam portion in the insulating layer.

A width of the second pad may be greater than a width of the first pad.

The base portion may further include an opening through which a portion of the second pad is exposed.

The printed circuit board may further include a third pad disposed on the first pad, and a fourth pad disposed on the second pad.

A side surface of the base portion may be in contact with side surfaces of the third pad and the fourth pad.

A thickness of each of the third pad and the fourth pad may be greater than a thickness of the base portion.

The protective layer may include a photosensitive material.

In a printed circuit board according to an example embodiment of the present inventive concept, a protective layer, protecting a pad, may have improved structural stability.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram of an example of an electronic device system;

FIG. 2 is a schematic perspective view of an example of an electronic device;

FIG. 3 is a schematic plan view of an example of a printed circuit board;

FIG. 4 is a cross-sectional view of a portion of the printed circuit board of FIG. 3;

FIG. 5 is an enlarged view of a protective layer according to an example;

FIG. 6 is an enlarged view of a protective layer according to an example;

FIG. 7 is a schematic cross-sectional view of another example of a printed circuit board; and

FIGS. 8 to 10 illustrate examples of a method of manufacturing a printed circuit board.

### DETAILED DESCRIPTION

Hereinafter, example embodiments of the present disclosure are described with reference to the accompanying drawings. The present disclosure may, however, be exemplified in many different forms and should not be construed as being limited to the specific example embodiments set forth herein. In addition, example embodiments of the present disclosure may be provided for a more complete description of the present disclosure to those skilled in the art. Accordingly, the shapes and sizes of the elements in the drawings may be exaggerated for clarity of description, and elements denoted by the same reference numerals in the drawings may be the same elements.

### Electronic Device

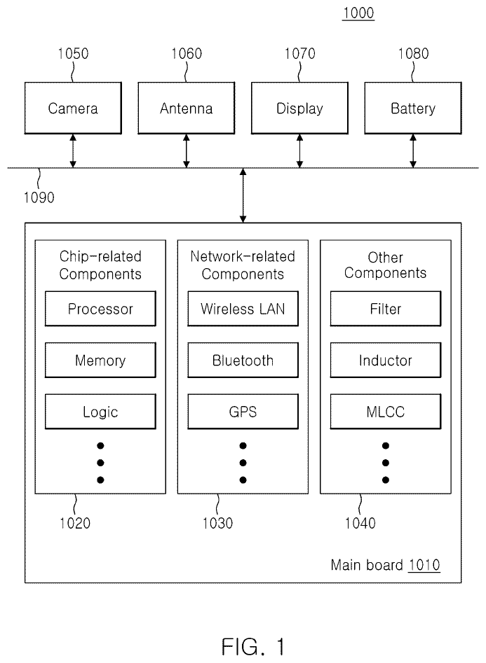

FIG. 1 is a schematic block diagram of an example of an electronic device system.

Referring to the drawings, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high-frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device used to process data.

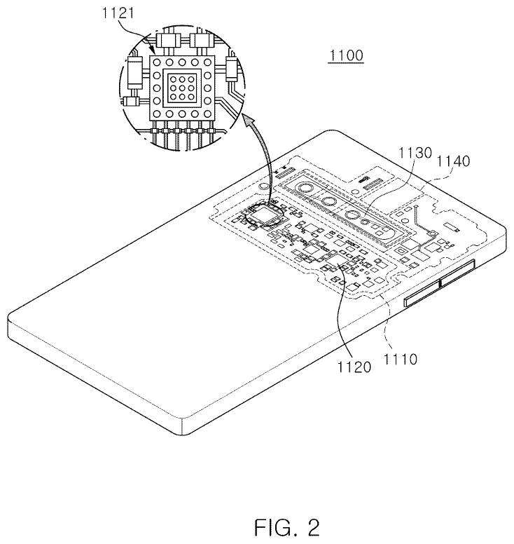

FIG. 2 is a schematic perspective view of an example of an electronic device.

Referring to the drawings, an electronic device may be, for example, a smartphone 1100. The motherboard 1110 may be accommodated in the smartphone 1100, and various electronic components 1120 may be physically and/or electrically connected to the motherboard 1110. In addition, other electronic components that may be or may not be physically and/or electrically connected to the motherboard 1110 may be accommodated therein, such as a camera module 1130 and/or a speaker 1140. A portion of the electronic components 1120 may be the chip-related components described above, for example, a component package 1121, but the present disclosure is not limited thereto. The component package 1121 may be in the form of a printed circuit board on which electronic components including active components and/or passive components are surface-mounted. The electronic device is not limited to the smartphone 1100, and may be other electronic devices, as described above.

### Printed Circuit Board

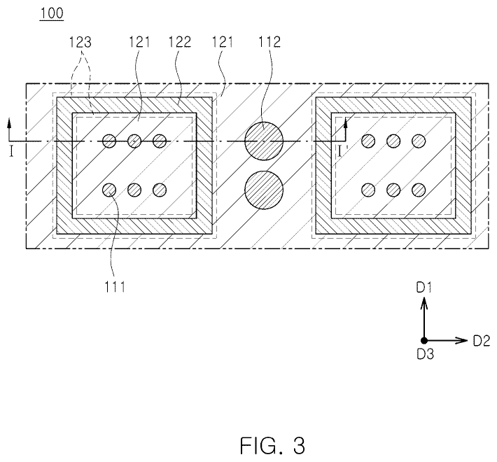

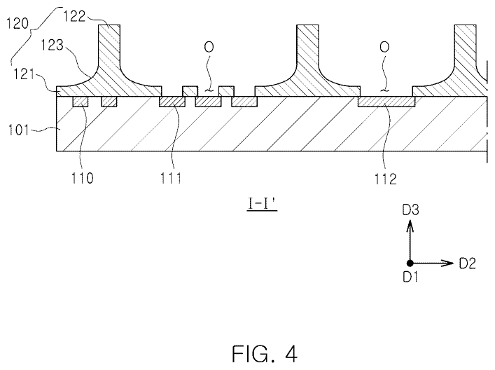

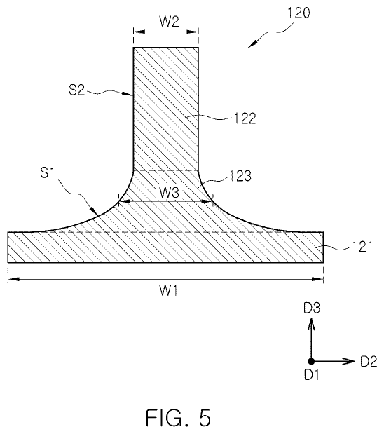

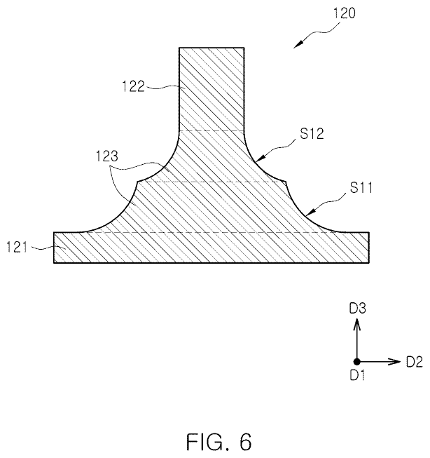

FIG. 3 is a schematic plan view of an example of a printed circuit board, and FIG. 4 is a cross-sectional view of a portion of the printed circuit board of FIG. 3. FIGS. 5 and 6 illustrate a specific form of a protective layer applicable to a printed circuit board according to the present example embodiment. Referring to FIGS. 3 to 5, a printed circuit board 100 according to the present example embodiment may include an insulating layer 101, first pads 111, and a protective layer 120. Here, the protective layer 120 may include a base portion 121, a dam portion 122, and a connection portion 123. The protective layer 120, including the dam portion 122, may effectively protect the printed circuit board 100 during an underfill process of a chip. For example, the protective layer 120 may protect second pads 112 in regions of the printed circuit board 100 positioned outside the dam portion 122. In addition, the base portion 121, the dam portion 122, and the connection portion 123, included in the protective layer 120, may be integrally formed rather than being manufactured using separate manufacturing processes. Accordingly, the protective layer 120 may include multiple layers, thereby preventing structural stability degradation that may occur due to stress concentration at a junction between the multiple layers. The protective layer 120, having an integral structure or a single body structure, may have improved structural stability, thereby contributing to improvement in the performance of the printed circuit board 100. Hereinafter, main components of the printed circuit board 100 will be described in detail. Regarding the definitions of a first direction D1, a second direction D2, and a third direction D3 in the drawings, the second direction D2 may be defined as a width direction of the first pads 111, the third direction D3 may be defined as a thickness direction of the first pads 111, and the first direction D1 may be defined as a direction, perpendicular to the second and third directions D2 and D3.

The insulating layer 101 may include an insulating material, and may have a multilayer structure. Here, the insulating material of the insulating layer 101 may include a thermosetting resin such as an epoxy resin, a thermoplastic resin such as polyimide, or a material including an inorganic filler, an organic filler, and/or a glass fiber (glass cloth, and/or glass fabric), together with the above-described resins. The insulating material may be a photosensitive material and/or a non-photosensitive material. For example, the insulating material may be an insulating material such as a solder resist (SR), an Ajinomoto build-up film (ABF), bismaleimide triazine (FR-4), prepreg (PPG), or resin-coated copper (RCC), an insulating material such as a copper lad laminate (CCL), or the like, but the present disclosure is not limited thereto, and other polymer materials may be used.

The first pad 111 may be disposed in the insulating layer 101, and may serve as a region connected to a semiconductor chip, a package, an interposer, or the like. The first pad 111, disposed on the insulating layer 101, may mean that the first pad 111 is disposed in the insulating layer 101 or on a surface of the insulating layer 101. As illustrated, the first pad 111 may have an upper surface exposed from the insulating layer 101, and a remaining portion buried in the insulating layer 101. The printed circuit board 100 may further include a conduct layer 110 and a second pad 112 in addition to the first pad 111. Here, the conduct layer 110 may be disposed in the insulating layer 101, and may have an upper surface covered by the base portion 121 of the protective layer 120. The second pad 112 may be disposed on the outside of the dam portion 122 of the protective layer 120 in the insulating layer 101, and may have a width greater than that of the first pad 111. In this case, the first pad 111 may serve as a chip mounting region, while the second pad 112 may serve as a connection region for a package, an interposer, or the like.

The conduct layer 110, the first pad 111, and the second pad 112 may include a metal having high electrical conductivity, which may include at least one selected from the group consisting of, for example, copper (Cu), aluminum (Al), silver (Ag), tin (Sn), gold (Au), nickel (Ni), lead (Pb), titanium (Ti), and alloys thereof, and may be implemented to have a multilayer structure, as necessary. In addition, the insulating layer 101 may further include a conduct layer, a pad, a conductive via, or the like, disposed on levels different from those the conduct layer 110, the first pad 111, and the second pad 112, in addition to the conduct layer 110, the first pad 111, and the second pad 112.

The protective layer 120 may be disposed on the insulating layer 101, and may protect the conduct layer 110, the first pad 111, the second pad 112, and the like. In the present example embodiment, the protective layer 120 may include a base portion 121, a dam portion 122, and a connection portion 123, and the base portion 121, the dam portion 122, and the connection portion 123 may be integrally formed. Here, the base portion 121 may have an opening O exposing a portion of the first pad 111. The dam portion 122 may be disposed on the base portion 121 and a part of the protective layer protruding from the base portion 121, and may have a width, less than that of the base portion 121. As illustrated in FIG. 3, the dam portion 122 may be formed to surround the first pad 111 in a lateral direction. However, the dam portion 122 may not surround the entire first pad 111, and a portion of the first pad 111 may be exposed. The connection portion 123 may be disposed between the base portion 121 and the dam portion 122. The connection portion 123 may have a width, greater than that of the dam portion 122 and less than that of the base portion 121. That is, among the base portion 121, the dam portion 122, and the connection portion 123, the base portion 121 may have a largest width W1, the dam portion 122 may have a smallest width W2, and the connection portion 123 may have an intermediate width W3. The widths W1, W2, and W3 of the base portion 121, the dam portion 122, and the connection portion 123 may be measured in a cross-section of the printed circuit board 100 with respect to a width in the second direction D2. To enhance measurement accuracy, a value obtained by averaging widths obtained from a plurality of cross-sections may be used. The width W1 of the base portion 121 may be defined as a width of a lowermost portion of the base portion 121, the width W2 of the dam portion 122 may be defined as a width of an uppermost portion of the dam portion 122, and the width W3 of the connection portion 123 may be defined as a width of the connection portion 123 at an intermediate point in the third direction D3.

As described above, in the present example embodiments, the base portion 121, the dam portion 122, and the connection portion 123, included in the protective layer 120, may be integrally formed, thereby improving structural stability. Specifically, when the base portion 121 and the dam portion 122 are formed using separate processes, for example, when a protective layer is implemented by laminating a plurality of solder resists, stress may be concentrated at a junction between the plurality of solder resists, causing cracks or the like. Accordingly, such a configuration may reduce an issue in which structural stability is degraded by the generation of cracks or the like. The protective layer 120 may include a photosensitive material, and may function as a solder resist. In order to implement the protective layer 120 having an integral structure or a single body structure, a method may be used in which the protective layer 120 is formed as a thick film and then etched to reduce a thickness of the protective layer 120. In some embodiments, the base portion 121, the dam portion 122, and the connection portion 123, included in the protective layer 120 may include the same materials or may be formed by same materials.

When the dam portion 122 is implemented in the above-described manner, the connection portion 123 having an intermediate width may be formed at a junction between the base portion 121 and the dam portion 122. In this case, the connection portion 123 may be implemented in the form of an inclined surface. More specifically, as illustrated in FIG. 5, the connection portion 123 may include a curved surface S1, which may reduce the effect of stress that may be applied to the periphery of the dam portion 122. Alternatively, a side surface S2 of the dam portion 122, spaced apart from the base portion 121, may have a planar surface. In this case, the planar surface S2 of the dam portion 122 may be perpendicular to an upper surface of the insulating layer 101. The planar surface S2 of the dam portion 122 may be a region that remains after an etching process, which is described below.

As illustrated in FIG. 4, a lower surface of the base portion 121 may be in contact with a region of the first pad 111, not exposed by the opening O. In addition, the base portion 121 may further include an opening O, exposing a portion of the second pad 112. In addition, a portion of the base portion 121 may cover an upper surface of the conductor layer 110.

More specific details of a shape of the connection portion 123 will be described with reference to FIG. 5. A width of the connection portion 123 may gradually increase or decrease in one direction. For example, the width of the connection portion 123 may gradually increase from an upper portion to a lower portion of the dam portion 122. In addition to the above-described form, as illustrated in the modification of FIG. 6, the connection portion 123 may include a plurality of side surfaces S11 and S12, discontinuously connected to each other. That is, the side surface S11 and the side surface S12 are abruptly connected to each other and do not have smooth integrated surface. The above-described multilayer structure of the connection portion 123 may be implemented by etching the protective layer 120 a plurality of times. In this case, the connection portion 123 may include a first side surface S11 and a second side surface S12 disposed in sequence from a position closer to the base portion 121. Here, each of the first and second side surfaces S11 and S12 may have a width gradually increasing from an upper portion to a lower portion of the dam portion 122. In addition, each of the plurality of side surfaces S11 and S12 of the connection portion 123 may include a curved surface.

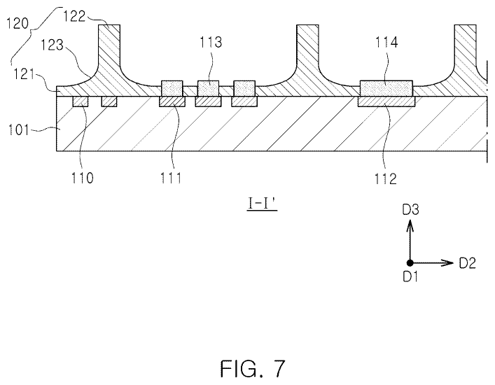

Another modification will be described with reference to FIG. 7. In the modification of FIG. 7, additional pads 113 and 114 may be further provided. Specifically, a third pad 113 may be disposed on the first pad 111, and a fourth pad 114 may be disposed on the second pad 112. The additionally provided third and fourth pads 113 and 114 may function as a top ball pad. When the third and fourth pads 113 and 114 are added, a side surface of the base portion 121 may be in contact with side surfaces of the third and fourth pads 113 and 114, as illustrated. In addition, a thickness of each of the third and fourth pads 113 and 114 may be greater than a thickness of the base portion 121.

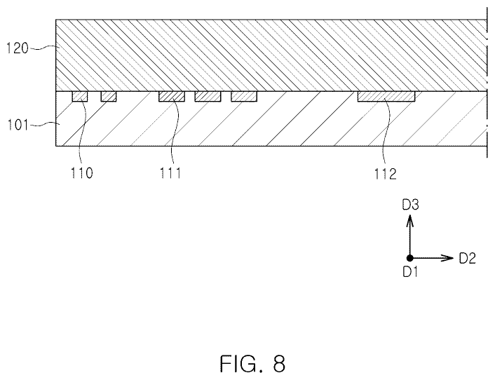

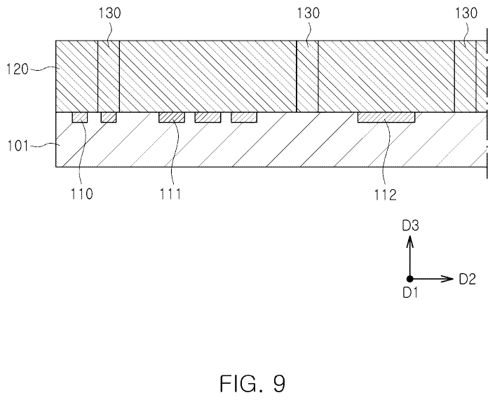

An example of a method of manufacturing a printed circuit board will be described with reference to FIG. 8 to FIG. 10. In the following description, a method of forming a protective layer 120 will mainly be described, and a conventional technique of manufacturing a printed circuit board may be applied to the formation of other components. First, referring to FIG. 8, the protective layer 120 may be formed on an insulating layer 101. Specifically, a photosensitive material may be coated as a thick film in consideration of a thickness required to implement a dam portion. A conduct layer, a pad, a conductive via, or the like may be provided in the insulating layer 101 or on a surface of the insulating layer 101. FIG. 9 illustrates an example in which the insulating layer 101 is provided with a conductor layer 110 and pads 111 and 112. The insulating layer 101 and a conduct layer provided therein may be formed using a substrate manufacturing method known in the art. In addition, when third and fourth pads 113 and 114 are provided on the first and second pads 111 and 112, respectively, the protective layer 120 may be formed after the formation of the third and fourth pads 113 and 114 so as to cover the third and fourth pads 113 and 114.

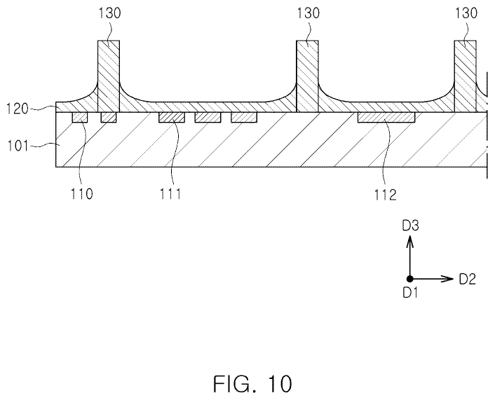

Subsequently, as illustrated in FIG. 9, a portion of the protective layer 120 may be exposed to form an exposure region 130, and the exposure region 130 may be a region corresponding to a dam portion. The exposure region 130 may remain without being removed in a subsequent etching process and may become a part of the dam portion. However, depending on how an etching process is performed, an exposure process may be performed in reverse. For example, regions of the protective layer 120, excluding a region indicated by reference numeral 130, may be exposed. Subsequently, as illustrated in FIG. 10, the regions of the protective layer 120, excluding the exposure region 130, may be etched to reduce a thickness of the protective layer 120. The etching process may be performed using a process used for a photolithography process known in the art. Here, the etching process may be performed such that, rather than being entirely removed, the regions excluding the exposure region 130 are partially reduced in thickness, leaving a remaining portion. In such a process, a connection portion that is in the above-described form may be formed. Subsequently, additional exposure and etching processes may be performed to expose the first and second pads 111 and 112, thereby forming the protective layer 120 that is in the above-described form.

Among other operations, operations the same as those in a method of manufacturing a printed circuit board according to an example or a method of manufacturing a printed circuit board according to another example may be applied to a printed circuit board according to another example, and thus a repeated description thereof will be omitted.

As used herein, a cross-sectional shape may refer to a cross-sectional shape of an object when the object is vertically cut, or a cross-sectional shape of the object when the object is viewed in a side-view. In addition, a shape on a plane may be a shape of the object when the object is horizontally cut, or a planar shape of the object when the object is viewed in a top-view or a bottom-view.

As used herein, an upper side, an upper portion, the upper surface, or the like is used to refer to a direction toward a surface on which an electronic component is mountable based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

As used herein, the term “an example embodiment” is provided to emphasize a particular feature, structure, or characteristic, and do not necessarily refer to the same example embodiment. In addition, the particular characteristics or features may be combined in any suitable manner in one or more example embodiments. For example, a context described in a specific example embodiment may be used in other example embodiments, even if it is not described in the other example embodiments, unless it is described contrary to or inconsistent with the context in the other example embodiments.

The terms used herein describe particular example embodiments only, and the present disclosure is not limited thereby. As used herein, singular forms “a,” “an,” and “the” are intended to include the plural forms as well, unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
an insulating layer;
a first pad disposed on or embedded in the insulating layer, exposing an upper surface of the first pad; and
a protective layer disposed on the insulating layer and the upper surface of the first pad,
wherein the protective layer includes: a base portion having an opening exposing a portion of the first pad; a dam portion disposed on the base portion, the dam portion having a width less than that of the base portion; and a connection portion between the base portion and the dam portion,
the connection portion has a width greater than a width of the dam portion and less than a width of the base portion.

2. The printed circuit board of claim 1, wherein a side surface of the connection portion includes a curved surface.

3. The printed circuit board of claim 1, wherein a side surface of the dam portion, spaced apart from the base portion, has a planar surface.

4. The printed circuit board of claim 3, wherein the planar surface is vertical with respect to an upper surface of the insulating layer.

5. The printed circuit board of claim 1, wherein a lower surface of the base portion is in contact with a region of the first pad, not exposed by the opening.

6. The printed circuit board of claim 1, further comprising:
a conductor layer disposed on or embedded in the insulating layer, the conductor layer having an upper surface covered by the base portion.

7. The printed circuit board of claim 1, wherein the connection portion has a width gradually increasing from an upper portion to a lower portion of the dam portion.

8. The printed circuit board of claim 1, wherein the connection portion includes a plurality of side surfaces, discontinuously connected to each other.

9. The printed circuit board of claim 8, wherein
the connection portion includes a first side surface and a second side surface disposed in sequence from a position closer to the base portion, and
each of the first and second side surfaces has a width gradually increasing from an upper portion to a lower portion of the dam portion.

10. The printed circuit board of claim 8, wherein each of the plurality of side surfaces includes a curved surface.

11. The printed circuit board of claim 1, further comprising:
a second pad disposed on or embedded in the insulating layer, disposing an upper surface of the second pad, in an area on which the dam portion is not disposed.

12. The printed circuit board of claim 11, wherein a width of the second pad is greater than a width of the first pad.

13. The printed circuit board of claim 11, wherein the base portion further includes an opening through which a portion of the second pad is exposed.

14. The printed circuit board of claim 11, further comprising:
a third pad disposed on the first pad; and
a fourth pad disposed on the second pad.

15. The printed circuit board of claim 14, wherein a side surface of the base portion is in contact with side surfaces of the third pad and the fourth pad.

16. The printed circuit board of claim 15, wherein a thickness of each of the third pad and the fourth pad are greater than a thickness of the base portion.

17. The printed circuit board of claim 1, wherein the protective layer includes a photosensitive material.

18. The printed circuit board of claim 1, wherein the base portion, the dam portion, and the connection portion are connected in one peace.
